(19) United States
(12) Patent Application Publication
(10) Pub. No.: US 2025/0386434 A9
(43) Pub. Date: Dec. 18, 2025

(54) FLUORORESIN LONG FILM, METAL-CLAD LAMINATE AND SUBSTRATE FOR CIRCUIT

(71) Applicant: DAIKIN INDUSTRIES, LTD., Osaka (JP)

(72) Inventors: Kenzo TAKAHASHI, Osaka (JP); Nobuyuki KOMATSU, Osaka (JP); Tatsuya HIGUCHI, Osaka (JP); Takeshi HAZAMA, Osaka (JP); Mayuko TATEMICHI, Osaka (JP); Hirokazu KOMORI, Osaka (JP); Hideaki TENKAJI, Osaka (JP); Masahiko KAWAMURA, Osaka (JP)

(73) Assignee: DAIKIN INDUSTRIES, LTD., Osaka (JP)

(21) Appl. No.: 19/028,921

(22) Filed: Jan. 17, 2025

Related U.S. Application Data
(63) Continuation of application No. PCT/JP2023/026941, filed on Jul. 24, 2023.

(30) Foreign Application Priority Data
Jul. 22, 2022 (JP) 2022-117314

(51) Int. Cl. H05K 1/03; C08F 214/26

(52) U.S. Cl. CPC H05K 1/0353; C08F 214/267

(57) ABSTRACT

Provided is a fluororesin long film that has high uniformity and does not deform when bonded to metal foil. A fluororesin long film including a fluororesin in which the number of unstable functional groups is less than 350 per 1×10⁶ carbon atoms, where a difference between each average film thickness in a travel direction at every 5 mm in a width direction and an average film thickness of entire surface is within 2 μm.

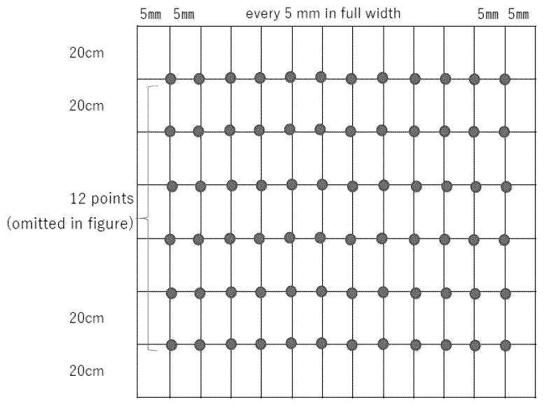

### CROSS REFERENCE TO RELATED APPLICATIONS

This application is a Rule 53 (b) Continuation of International Application No. PCT/JP2023/026941 filed Jul. 24, 2023, which claims priority from Japanese Patent Application No. 2022-117314 filed Jul. 22, 2022, the respective disclosures of all of the above are incorporated herein by reference in their entirety.

### TECHNICAL FIELD

The present disclosure relates to a fluororesin long film, a metal-clad laminate and a substrate for circuits.

### BACKGROUND ART

Epoxy resin and polyimide resin have been widely used for circuit boards as an insulation layer. In recent years, for high frequency circuit boards used for applications in a high frequency region of a few tens of GHz, structures in which an insulation layer made of fluororesin is formed on metal foil have been proposed in consideration of dielectric properties and hygroscopic properties (Patent Literature 1). The fluororesin film used for this purpose is required to be bonded to metal foil without deformation to obtain a low transmission loss substrate that is less likely to cause disconnection of signal lines.

In the production of long films by extrusion forming in which a resin is melted and formed, attempts have been made to obtain uniformity in thickness of the resin (Patent Literatures 2 and 3).

As a fluororesin, a resin with a reduced number of unstable functional groups is known (Patent Literature 4).

### CITATION LIST

### Patent Literature

Patent Literature 1: Japanese Patent Laid-Open No. 2021-160856
Patent Literature 2: Japanese Patent Laid-Open No. 2012-187874
Patent Literature 3: Japanese Patent Laid-Open No. 2012-118238
Patent Literature 4: Japanese Patent Laid-Open No. 2009-059690

### SUMMARY

The present disclosure is:
a fluororesin long film comprising a fluororesin in which the number of unstable functional groups is less than 350 per 1×10⁶ carbon atoms, wherein, regarding the average film thickness of entire surface (a), the difference (b-a) between the maximum value (b) of the average film thicknesses of 12 points in the travel direction each measured at every 5 mm in the width direction and the average film thickness of entire surface is within 2 μm.

### Advantageous Effect of Invention

The fluororesin film of the present disclosure has the advantageous effect of few defects in lamination and being capable of providing excellent adhesion to metal foil.

### BRIEF DESCRIPTION OF DRAWING

The FIGURE is a schematic diagram illustrating a method for measuring an average film thickness of the present invention.

### DESCRIPTION OF EMBODIMENTS

Hereinafter the present disclosure will be described in more detail.

When known fluororesin films are actually bonded to metal foil or the like and used, they have difficulty in bonding uniformly because the deformation of the film occurs. In particular, for laminates used in the electrical and electronic fields, it has been found that inadequate uniformity of bonding affects their electrical properties.

When producing a film by extrusion melt forming, thickness deviation causes a difference in thickness not only at the end and center of the film but also in the center of the film. In this case, when the film is made into a roll film, a bump like a convex band called a gauge band is generated. When a gauge band is present, appearance becomes poor, and loosening and wrinkling of the film occur at the time of film formation and during transport and cause crease-like appearance defects. It is known, in particular, that fluororesin is difficult to form a uniform film, unlike other resins. This is believed because fluororesin, unlike other resins, has a small surface free energy, thus when the resin in the T-die contacts the first roll from the end where the resin flows out, it is difficult to spread evenly on the roll surface.

In addition, when a laminate is prepared using this film, it is necessary to stack the film with tension to prevent loosening and wrinkling of the film, which causes residual distortion and curling of the laminate. Furthermore, when the film is used for a printed circuit board or the like, it can cause non-uniformity in bonding and disconnection of signal lines.

In a laminate with stacking of a fluororesin film and metal foil, in particular, it is required that the characteristic impedance is within a specific range. During an investigation of a method for controlling such characteristic impedance, it has been found that the uniformity in film thickness of the fluororesin film is important, and it has been found that the fluororesin film of the present disclosure is particularly suitable.

An object of the present disclosure is to provide a film having few gauge bands and capable of uniformly bonding to metal foil. For this, it has been found that adjusting the production method of the film and further using a resin with a small number of unstable functional groups as a resin used can suppress the generation of gauge bands, thereby completing the present disclosure.

The present disclosure is a fluororesin long film comprising a fluororesin in which the number of unstable functional groups is less than 350 per 1×10⁶ carbon atoms, wherein a difference between a maximum value of average film thicknesses in a travel direction each measured at every 5 mm in a width direction and an average film thickness of entire surface is within 2 μm. Hereinafter, each of these points will be described in more detail.

### (Long Film)

The fluororesin film of the present disclosure is a long film. The long film means that the length of the film is 3 m or more. The width of the film is not limited, but is preferably 20 cm or more, more preferably 50 cm or more, and most preferably 120 cm or more. It is also preferable that the fluororesin long film is a roll film.

It is preferable that such a fluororesin long film has a thickness in the range of 12.5 to 150 μm. Those having such a thickness range can be particularly suitable for the applications described above.

The above-mentioned thickness means the average film thickness of entire surface, which will be described in detail below.

Such a fluororesin long film easily has problems due to generation of gauge bands described above. Thus, suppressing gauge bands is particularly important.

(Difference between maximum value of average film thicknesses in travel direction each measured at every 5 mm in width direction and average film thickness of entire surface is within 2 μm)

This requirement shows the absence of gauge bands as a specific numerical value. More specifically, it means that there are no areas of extremely thick compared to the average film thickness. In the measurement of such parameters, thicknesses of 12 points are measured at every 20 cm in a travel direction at every 5 mm in the width direction. Then, in the same width direction, the thicknesses of 12 points in the travel direction are averaged. The obtained values are average film thicknesses in the travel direction each measured at every 5 mm in the width direction.

Then, the arithmetic average of all values of the average film thicknesses in the travel direction measured at every 5 mm in the width direction in this way is taken as the average film thickness of entire surface.

It is an important point in the present disclosure that, when comparing the average film thickness of entire surface obtained in this way with the maximum value of average film thicknesses in the travel direction each measured at every 5 mm in the width direction, the maximum value of each average film thicknesses in the travel direction at every 5 mm in the width direction is equal to or less than the average value+2 μm.

This means that the film has an extremely high uniformity in thickness. When a long film with such a high uniformity is taken up, since the difference in thickness in that state is small, a film with high uniformity can be taken up in an excellent state. This is preferable in that it is difficult to cause problems in the subsequent process of lamination with metal foil, and further in that the characteristic impedance within an excellent range can be provided.

In addition, although metal-clad laminates laminated with metal foil are susceptible to curling, the metal-clad laminate obtained using the fluororesin long film of the present disclosure is advantageously resistant to curling. The method for obtaining such a film will be described later.

### (Fluororesin)

The number of unstable functional groups of the fluororesin constituting the fluororesin film of the present disclosure is less than 350 per 1×10⁶ carbon atoms in a main chain of the fluororesin. In other words, the fluororesin has a small number of unstable functional groups. Fluororesins are prone to have unstable functional groups during polymerization reactions, and such unstable functional groups tend to cause gas generation by thermal melting during film forming. Since such gas generation can cause the thickness unevenness of the fluororesin film, it is preferable that the fluororesin film comprises such a fluororesin having a small number of unstable functional groups.

Such fluororesin in which unstable functional groups are within a specific numerical range may be produced by a method including adjusting conditions in production (in polymerization reaction), a method of subjecting a fluororesin after polymerization to fluorine gas treatment, heat treatment, supercritical gas extraction, and the like to reduce the number of unstable functional groups, and the like. Fluorine gas treatment (fluorination treatment) is preferred because it is excellent in processing efficiency and part or all of the unstable functional groups are converted into —CF₃ to form a stable terminal group. It is preferable to use fluororesin in which the number of unstable functional groups is reduced because dielectric loss tangent is reduced and loss of electric signals is reduced.

The number of unstable functional groups of the fluororesin of the present disclosure is less than 350 per 1×10⁶ carbon atoms.

With such a small number of unstable functional groups, gas generation during melt forming can be suppressed, and it is possible to suppress thickness deviation due to the uneven flow of melted resin caused by gas stagnating near the slit of the T-die.

The number of unstable functional groups is more preferably less than 250, further preferably less than 100, still further preferably less than 20, and most preferably less than 10 per 1×10⁶ carbon atoms in the main chain of the fluororesin.

Specific examples of unstable functional groups include functional groups such as —COF, —COOH free, —COOH bonded, —CH₂OH, —CONH₂, and —COOCH₃.

The number of unstable functional groups is specifically measured by the following method. First, the fluororesin is melted and compression-formed to prepare a film having a thickness of 0.25 to 0.3 mm. The film is analyzed by Fourier transform infrared spectrophotometry to obtain an infrared absorption spectrum of the fluororesin, and a differential spectrum relative to a base spectrum of resin which is completely fluorinated and has no functional group is obtained.

The number of unstable functional groups per 1×10⁶ carbon atoms in the fluororesin is calculated from the peak of absorption of a specific functional group appearing in the differential spectrum based on the following formula (A).

$$N = I \times K / t \qquad ( A )$$

I: Absorbance
K: Coefficient of compensation
t: Thickness of film (mm)

The absorption frequency, molar extinction coefficient and coefficient of compensation for the unstable functional group in the present description will be described in Table 1 for reference. The molar extinction coefficient is determined from the FT-IR data of a model low molecular weight compound.

TABLE 1

| | Absorption | Molar extinction | | |
|---|---|---|---|---|
| Unstable | frequency | coefficient | Coefficient of | |
| terminal group | (cm−1) | (1/cm/mol) | compensation | Model compound |
| —COF | 1883 | 600 | 388 | C₇F₁₅COF |
| —COOH (free) | 1815 | 530 | 439 | H(CF₂)₆COOH |
| —COOH | 1779 | 530 | 439 | H(CF₂)₆COOH |
| (bonded) | | | | |
| —COOCH3 | 1795 | 680 | 342 | C₇F₁₅COOCH₃ |
| —CONH2 | 3436 | 506 | 460 | C₇F₁₅CONH₂ |
| —CH2OH | 3648 | 104 | 2236 | C₇F₁₅CH₂OH |
| —CF2H | 3020 | 8.8 | 26485 | H(CF₂CF₂)₃CH₂OH |
| —OC(═O)O—R | 1817 | — | 1426 | — |

The above fluorination may be performed by bringing fluororesin which has not been fluorinated into contact with a fluorine-containing compound.

Examples of fluorine-containing compounds described above include, but are not limited to, a source of fluorine radicals, which generates a fluorine radical under conditions of fluorination. Examples of sources of fluorine radicals include F₂ gas, CoF₃, AgF₂, UF₆, OF₂, N₂F₂, CF₃OF and fluorinated halogen (e.g., IF₅, CIF₃).

While the concentration of the above source of fluorine radicals such as F₂ gas may be 100%, the source is used after being mixed with inert gas and diluted to preferably 5 to 50% by mass, more preferably 15 to 30% by mass. Examples of inert gas described above include nitrogen gas, helium gas and argon gas, and nitrogen gas is preferred from the economic point of view.

The condition of fluorination is not limited. Molten fluorine resin may be brought into contact with a fluorine-containing compound at usually the melting point of the fluorine resin or lower, preferably a temperature of 20 to 220° C. and more preferably 100 to 200° C. The time of fluorination is usually 1 to 30 hours, and preferably 5 to 25 hours. For the above fluorination, it is preferable that fluorine resin which has not been fluorinated is brought into contact with fluorine gas (F₂ gas).

In the present description, the content of the respective monomer units constituting fluorine resin may be calculated by appropriately combining NMR, FT-IR, elemental analysis and fluorescent X-ray analysis depending on the type of monomers.

The resin constituting the fluororesin film of the present disclosure is not limited and may be a polymer including a fluorine atom. A fluororesin which can be melt molded is more preferred as fluororesin. Examples thereof include a tetrafluoroethylene⋅perfluoroalkyl vinyl ether copolymer (PFA), a copolymer including a chlorotrifluoroethylene (CTFE) unit (CTFE copolymer), a tetrafluoroethylene⋅hexafluoropropylene copolymer (FEP), a tetrafluoroethylene⋅ethylene copolymer (ETFE), polychlorotrifluoroethylene (PCTFE), a chlorotrifluoroethylene⋅ethylene copolymer (ECTFE), polyvinylidene fluoride (PVDF), polyvinyl fluoride (PVF), a tetrafluoroethylene⋅hexafluoropropylene⋅vinylidene fluoride copolymer (THV) and a tetrafluoroethylene⋅vinylidene fluoride copolymer.

Of these fluororesins which can be melt molded, a tetrafluoroethylene⋅perfluoroalkyl vinyl ether copolymer (PFA) and a tetrafluoroethylene⋅hexafluoropropylene copolymer (FEP) are preferred.

Use of the above fluororesin which can be melt molded allows melt molding, and thus the cost of processing can be lower than cases using PTFE. Furthermore, adhesiveness when bonding to metal foil can be improved.

The above PFA has a melting point of preferably 180 to 340° C., more preferably 230 to 330° C. and further preferably 280 to 320° C. The above melting point corresponds to the local maximum value in a heat-of-fusion curve when temperature is increased at a rate of 10° C./minute using a differential scanning calorimeter (DSC).

The above PFA is not limited, and a copolymer in which the molar ratio between the TFE unit and the PAVE unit (TFE unit/PAVE unit) is 70/30 or more and less than 99.5/0.5 is preferred. The molar ratio is more preferably 70/30 or more and 98.9/1.1 or less, and further preferably 80/20 or more and 98.5/1.5 or less. When the ratio of the TFE unit is very low, mechanical properties tend to be reduced. When the ratio of the TFE unit is very high, the resin has extremely high melting point and moldability tends to be reduced. The above PFA may be a copolymer consisting of only TFE and PAVE or is preferably a copolymer in which the ratio of the monomer unit derived from a monomer copolymerizable with TFE and PAVE is 0.1 to 10% by mole and the total of the TFE unit and the PAVE unit is 90 to 99.9% by mole. Examples of monomers copolymerizable with TFE and PAVE include HFP, a vinyl monomer represented by CZ₃Z₄=CZ₅ (CF₂)ₙZ₆ (in which Z₃, Z₄ and Z₅ are the same or different and represent a hydrogen atom or a fluorine atom, Z₆ represents a hydrogen atom, a fluorine atom or a chlorine atom, and n represents an integer of 2 to 10), and an alkyl perfluorovinyl ether derivative represented by CF₂=CF—OCH₂—Rf₇ (in which Rf₇ represents a perfluoroalkyl group having 1 to 5 carbon atoms). Examples of other copolymerizable monomers include a cyclic hydrocarbon monomer having an acid anhydride group. Examples of acid anhydride monomers include itaconic anhydride, citraconic anhydride, 5-norbornene-2,3-dicarboxylic anhydride and maleic anhydride. One of the acid anhydride monomers may be used alone or two or more of them may be used in combination.

The above PFA has a melt flow rate (MFR) of preferably 0.1 to 50 g/10 minutes, more preferably 0.5 to 40 g/10 minutes, and further preferably 1.0 to 30 g/10 minutes. In the present description, MFR is obtained by measurement in accordance with ASTM D3307 under conditions of a temperature of 372° C. and a load of 5.0 kg.

The above FEP is not limited and a copolymer in which the molar ratio between the TFE unit and the PAVE unit (TFE unit/PAVE unit) is 70/30 or more and less than 99/1 is preferred. The molar ratio is more preferably 70/30 or more and 98.9/1.1 or less, and further preferably 80/20 or more and 97/3 or less. When the ratio of the TFE unit is very low, mechanical properties tend to be reduced. When the ratio of the TFE unit is very high, the resin has extremely high melting point and moldability tends to be reduced. FEP is also preferably a copolymer in which the ratio of the monomer unit derived from a monomer copolymerizable with TFE and HFP is 0.1 to 10% by mole and the total of the TFE unit and the HFP unit is 90 to 99.9% by mole. Examples of monomers copolymerizable with TFE and HFP include an alkyl perfluorovinyl ether derivative.

The above FEP has a melting point of preferably 150 to 320° C., more preferably 200 to 300° C. and further preferably 240 to 280° C. The above melting point corresponds to the local maximum value in a heat-of-fusion curve when temperature is increased at a rate of 10° C./minute using a differential scanning calorimeter (DSC).

The above FEP has MFR of preferably 0.01 to 100 g/10 minutes, more preferably 0.1 to 50 g/10 minutes, further preferably 1 to 40 g/10 minutes, and particularly preferably 1 to 30 g/10 minutes.

The fluororesin film according to the present disclosure may include a component other than fluororesin. Examples of components which the film may include include, but are not limited to, a filler such as silica particles and glass staple fiber and thermosetting resin and thermoplastic resin which do not contain fluorine. The content of the components other than the fluororesin is not limited, but is more preferably 80% by mass or less, and further preferably 70% by mass or less.

The fluororesin-containing composition according to the present disclosure may include spherical silica particles. Spherical silica particles improve flowability of resin, and molding is easy even when a large amount of silica is mixed.

The above spherical silica particles mean those which are substantially a sphere, and have a sphericity of preferably 0.80 or more, more preferably 0.85 or more, further preferably 0.90 or more, and most preferably 0.95 or more. Sphericity is calculated from the area and the circumference of a particle observed in a micrograph taken by SEM based on (sphericity)= {4π×(area)÷(circumference)2}. A sphericity close to 1 means that the particle is close to a sphere. More specifically, an arithmetic average value of 100 particles measured using an image processing device (FPIA-3000 made by Spectris) is used.

The spherical silica particle preferably has a D90/D10 of 2 or more (preferably 2.3 or more, 2.5 or more) and D50 of 10 μm or less when volumes of particles with small particle size are integrated. The spherical silica particle has a D90/D50 of preferably 1.5 or more (more preferably 1.6 or more). The spherical silica particle has a D50/D10 of preferably 1.5 or more (more preferably 1.6 or more). Spherical silica particles with small particle size can enter into the gap between spherical silica particles with large particle size, and this provides excellent filling properties and improves flowability. In particular, it is preferable that in the particle size distribution, frequencies at the side of small particle size are high compared to the Gaussian curve. The particle size may be measured by a laser diffraction scattering particle size distribution meter. Furthermore, it is preferable that coarse particles with a predetermined particle size or more are removed by a filter and the like.

The above spherical silica particle has a water absorption of preferably 1.0% or less, and more preferably 0.5% or less. Water absorption is based on the mass of dried silica particles. For the measurement of water absorption, a dried sample is left at 40° C. and 80% RH for 1 hour and the content of water generated when the sample is heated at 200° C. is measured by a Karl Fischer moisture analyzer, and water absorption is calculated.

For the above spherical silica particles, the fluororesin composition is heated at 600° C. for 30 minutes in air to burn the fluororesin and the spherical silica particles are collected, and then the above parameters may be measured using the above method.

The silica powder according to the present invention may be surface-treated. Previous surface treatment can suppress aggregation of silica particles and allows silica particles to be dispersed well in the resin composition.

The above surface treatment is not limited and any known surface treatment may be used. Specific examples include a treatment using a silane coupling agent such as epoxy silane, amino silane, vinyl silane and acrylic silane having a functional group, hydrophobic alkyl silane, phenyl silane and fluorinated alkyl silane, a plasma treatment and a fluorination treatment.

Examples of silane coupling agents described above include epoxy silane such as γ-glycidoxypropyl triethoxysilane and β-(3,4-epoxycyclohexyl)ethyltrimethoxysilane, amino silane such as aminopropyl triethoxysilane and N-phenylaminopropyl trimethoxysilane, vinyl silane such as vinyl trimethoxysilane and acrylic silane such as acryloxy trimethoxysilane.

For the above spherical silica, commercially available silica particles which satisfy the above features may also be used. Examples of commercially available silica particles include Denka Fused Silica FB Grade (made by Denka Company Limited), Denka Fused Silica SFP Grade (made by Denka Company Limited), EXCELICA (made by Tokuyama Corporation), high purity synthesized spherical silica ADMAFINE (made by Admatechs company limited), ADMANANO (made by Admatechs company limited), and ADMAFUSE (made by Admatechs company limited).

When the spherical silica is mixed, in the mixing amount thereof, the mixing ratio of silica is preferably more than 40% by mass with respect to the mass of the fluororesin long film. The mixing ratio within the above range is preferable in that the linear expansion coefficient and formability can be balanced and a fluororesin composition having both of these properties can be easily made. The mixing ratio is more preferably 50% by mass or more, and further preferably 60% by mass or more. The upper limit of the mixing ratio is not limited, but more preferably 80% by mass or less, and further preferably 70% by mass or less.

### (Method for Producing Fluororesin Long Film of Present Disclosure)

The fluororesin long film of the present disclosure requires, in addition to using a fluororesin having a small number of unstable functional groups as described above, increasing uniformity in its production method. The fluororesin long film of the present disclosure is generally produced by extrusion melt forming in which a melted resin is extruded from a T-die into a film shape, cooled, and then taken up.

In such extrusion melt forming, the thickness of the resin film is particularly affected by the air gap distance from the end where the resin in a T-die flows out to a point where the resin contacts with the first roll, the MFR of the resin used, the melting temperature during film production, the pressure, the slit width of the T-die, the gap width, and the like. Accordingly, adjusting these appropriately can provide a smooth resin film satisfying the parameters described above.

The air gap distance from the end where the resin in a T-die flows out to a point where the resin contacts with the first roll is preferably 65 mm or less. That is, shortening the air gap reduces the thickness unevenness of the film by reducing the interposition of the air layer between the melt and the first roll.

Furthermore, adjusting MFR is also preferable. The lower the viscosity of the melted resin, the more intervening air layer described above. Thus, the melt flow rate (MFR) is preferably 0.1 to 50 g/10 minutes, more preferably 0.5 to 40 g/10 minutes, and further preferably 1.0 to 30 g/10 minutes. The above-described MFR is a value measured under the measurement conditions described in Examples.

It is also preferable to adjust the melting temperature, and it is preferable to select a temperature range such that the above-described MFR value can be obtained. Specifically, although the suitable melting temperature varies depending on the resin type, the molecular weight of the resin, or the like, it is preferable to adjust and set the temperature within the range of 340 to 370° C. such that MFR of the resin is within a predetermined range.

### (Oxygen Element Percentage of Surface)

In the film according to the present disclosure, an oxygen element percentage as measured when heat treatment is performed at 180° C. for 3 minutes and then the state of one or both surfaces of the film is observed by ESCA may be 1.5 atom % or more. The above-described oxygen element percentage is more preferably 1.8 atom % or more, and further preferably 2.0 atom % or more.

Fluororesin films generally have low adhesiveness to other materials. To improve the adhesiveness to other materials, the film obtained by extrusion may be subjected to a surface treatment to increase the oxygen element percentage and improve the adhesiveness and to set the oxygen element percentage of the surface within the above-described range.

The film according to the present disclosure may be a fluorine film in which a difference between the oxygen element percentage when the state of the surface of the film is observed by scanning X-ray photoelectron spectroscopy (XPS/ESCA) and the oxygen element percentage measured by scanning X-ray photoelectron spectroscopy (XPS/ESCA) after etching the film by argon gas cluster ion beams at an incident angle of 45° in the direction of the depth for 15 minutes is 1.0 atom % or more. By increasing only the oxygen element percentage of the surface which contributes to adhesion, sufficient adhesion strength can be achieved without reducing dielectric properties.

The heat treatment at 180° C. for 3 minutes means that the film is put on a metal tray and heat-treated in an electric oven in air atmosphere.

When the fluororesin film according to the present disclosure is laminated with a different material, it is preferable to use a film with an absolute value of the rate of dimensional change in MD and TD before and after heat treatment of 1.0% or less as measured when the film is heat-treated at 180° C. for 10 minutes and then cooled to 25° C. In the present disclosure, for the rate of dimensional change, marks are put at intervals of 180 mm on a film sample which has been cut into a 300 mm square, the sample is heat-treated for 10 minutes in air atmosphere in an electric oven set at 180° C. without load and cooled to 25° C., and the distance between the marks on the film is measured in the MD direction and the TD direction respectively and the rate of dimensional change is calculated from the amount of change in the distance between the marks before and after the heat treatment.

To obtain a fluororesin film having such a rate of dimensional change, it is preferable to perform an annealing treatment as described in detail below.

It is more preferable that the resin film of the present disclosure has a dielectric loss tangent at 10 GHz of less than 0.0015. The dielectric loss tangent in that range is preferred because loss of electric signals in the circuit can be kept low. The fluororesin film has a dielectric loss tangent of more preferably less than 0.0013, and further preferably less than 0.0010.

To set the dielectric loss tangent to the above range, it is preferable to use resin in which the number of unstable functional groups is small. It is more preferable to use a fluororesin which has been fluorinated.

The above fluororesin film has an adhesion strength of preferably 0.8 N/mm or more when bonded to metal foil having a surface roughness Rz of 1.5 μm or less under conditions of a temperature of the melting point or more and the melting point +30° C. or less, a pressure of 1.5 to 3.0 MPa and a time of 300 to 600 seconds using a vacuum heat press. The adhesion strength as used herein means adhesion strength of a laminate prepared by bonding under the above conditions, which is measured under the conditions described in Examples.

The method of surface modification is not limited, and the surface may be modified by any known method. It should be noted that such surface modification can be applied to the obtained resin film having excellent uniformity in thickness in the manner described above.

For surface modification of fluororesin film, a traditional discharge treatment such as a corona discharge treatment, a glow discharge treatment, a plasma discharge treatment and a sputtering treatment may be used. For example, surface free energy may be controlled by introducing, for example, oxygen gas, nitrogen gas or hydrogen gas into discharge atmosphere. Alternatively, the surface to be modified is exposed to atmosphere of an organic compound-containing inert gas, and high frequency voltage is applied between electrodes to generate discharge and form active species on the surface. Then the functional group of the organic compound is introduced thereinto or a polymerizable organic compound is graft-polymerized to allow the surface modification. Examples of inert gases described above include nitrogen gas, helium gas and argon gas.

Examples of organic compounds in the organic compound-containing inert gas include polymerizable or non-polymerizable oxygen atom-containing organic compounds such as vinyl esters such as vinyl acetate and vinyl formate; acrylates such as glycidyl methacrylate; ethers such as vinyl ethyl ether, vinyl methyl ether and glycidyl methyl ether; carboxylic acids such as acetic acid and formic acid; alcohols such as methyl alcohol, ethyl alcohol, phenol and ethylene glycol; ketones such as acetone and methyl ethyl ketone; carboxylates such as ethyl acetate and ethyl formate; and acrylic acids such as acrylic acid and methacrylic acid. Of them, vinyl esters, acrylates and ketones are preferred, and in particular vinyl acetate and glycidyl methacrylate are preferred because the modified surface is less likely to be deactivated, i.e., has long life and can be easily handled.

The concentration of the organic compound in the above organic compound-containing inert gas varies depending on its type and the type of fluororesins of which surface is to be modified. The concentration is usually 0.1 to 3.0% by volume, and preferably 0.1 to 1.0% by volume. Conditions of discharge may be appropriately selected depending on the intended degree of surface modification, the type of fluororesins and the type and the concentration of organic compounds. Usually the discharge treatment is performed in the amount of discharge of 50 to 1500 W·minute/m², and preferably 70 W·minute/m² or more and 1400 W·minute/m² or less. The discharge treatment may be performed at any temperature of 0° C. or more to 100° C. or less. The temperature is preferably 80° C. or less in consideration of elongation and wrinkles of film. For the degree of surface modification, an abundance of oxygen element in observation by ESCA is 2.0% or more, preferably 2.5% or more, more preferably 3.0% or more, and further preferably 3.5% or more in consideration of reduction of adhesiveness on the surface due to heat in post-processing. The upper limit is not limited, but is preferably 25.0% or less in consideration of productivity and impacts on other physical properties. The abundance of nitrogen element is not limited, but is preferably 0.1% or more. The fluororesin film has a thickness of preferably 2.5 to 1,000 μm, more preferably 5 to 500 μm and further preferably 12.5 to 150 μm per film.

### (Annealing Treatment)

The fluororesin film of the present disclosure may be one subjected to an annealing treatment after the above surface treatment. As described above, the fluororesin film of the present disclosure is required to have dimensional stability at the time of bonding to metal foil. It is thus preferable that the fluororesin film has a small shrinkage rate during heating.

Fluororesin films obtained by extrusion melt forming often have heat shrinkage due to residual internal stress. Such heat shrinkage adversely affects the dimensional stability when bonded to metal foil. It is thus preferable to release internal stress by performing an annealing treatment. Annealing treatment may be performed by heat treatment. In this heat treatment, for example, film may be passed through a heating furnace by a roll-to-roll method.

It is preferable that in the production of the fluororesin film of the present disclosure, annealing treatment is performed after the above corona discharge treatment. Furthermore, heat treatment may be performed in the process of lamination of the film and other materials such as metal foil. These heat treatments cause a reduction in the amount of oxygen on the surface of the fluororesin film. Thus, it is preferable to modify the surface under conditions that provide a sufficient amount of oxygen on the surface when the fluororesin film and other materials such as metal foil are actually stacked.

The temperature of annealing treatment is preferably the glass transition temperature −20° C. or more and less than the melting point, more preferably the glass transition temperature or more and the melting point −20° C. or less, and further preferably the glass transition temperature or more and the melting point −60° C. or less. The time of annealing treatment is not limited, and may be appropriately adjusted to, for example, 0.5 to 60 minutes.

When the film is heated by the above roll-to-roll method, the tension may be appropriately set depending on the thickness of the film and the set temperature, and is preferably 20 N/m or less. Heating under these conditions is preferable because internal stress can be sufficiently released and dimensional change and the like does not occur.

The order of the above surface treatment and annealing treatment is not limited. The number of times of the respective steps to be executed is not limited to once, either, and may be executed twice or more.

The fluororesin film of the present disclosure may be stacked to other substrates and used as a sheet for a printed wiring board. The fluororesin film of the present disclosure has a thickness of preferably 2.5 to 1,000 μm, more preferably 5 to 500 μm, and further preferably 7 to 150 μm. The thickness may be selected in consideration of the balance between electric properties and linear expansion coefficient of the laminate and the like.

The present disclosure also includes a laminate in which metal foil is bonded to one or both surfaces of the above fluororesin film. As described above, the film comprising the fluororesin according to the present disclosure has excellent adhesiveness with excellent uniformity of the obtained thickness. It is thus possible to stack without applying excessive tension to the film to eliminate gauge bands derived from the gauge bands when bonding. As a result, the internal stress remaining in the stacked film can be suppressed, and a laminate without curls can be provided, which is another advantage.

It is preferable that the above metal foil has Rz of 1.5 μm or less. In other words, the fluororesin composition according to the present invention has excellent adhesion even to highly smooth metal foil having Rz of 1.5 μm or less. The metal foil may have Rz of 1.5 μm or less on at least the surface to be bonded to the above fluororesin film, and the value of Rz on the other surface is not limited.

The thickness of the metal foil is not limited, and the copper foil has a thickness of preferably 1 to 100 μm, more preferably 5 to 50 μm, and further preferably 9 to 35 μm.

The metal foil described above is not limited, but is preferably a copper foil. The above copper foil is not limited and specific examples thereof include rolled copper foil and electrolytic copper foil.

Copper foil having Rz of 1.5 μm or less is not limited and commercially available copper foil may be used. Examples of commercially available copper foil having Rz of 1.5 μm or less include electrolytic copper foil CF-T9DA-SV-18 (thickness 18 μm, Rz 0.85 μm) (made by Fukuda Metal Foil & Powder Co., Ltd.).

The above metal foil may be surface-treated to improve adhesion strength to the fluororesin film of the present disclosure.

The surface treatment includes, but is not limited to, a silane coupling treatment, a plasma treatment, a corona treatment, a UV treatment and an electron beam treatment. The reactive functional group of the silane coupling agent is not limited, and the silane coupling agent may preferably include at least one group selected from an amino group, a (meth)acrylic group, a mercapto group and an epoxy group at the terminal in view of adhesion to the resin substrate. Examples of hydrolytic groups include, but are not limited to, an alkoxy group such as a methoxy group and an ethoxy group. An anti-rust layer (an oxide coating such as chromate) and a heat resistant layer may be formed on the metal foil used in the present disclosure.

Surface-treated metal foil having a surface-treated layer of the above silane compound on the surface may be produced by preparing a solution containing a silane compound and surface treating the metal foil using the solution.

The metal foil may have a roughened layer on the surface in order to increase adhesion to the resin substrate and the like.

If roughening treatment is likely to degrade properties required in the present disclosure, the amount of roughening particles to be electrodeposited on the metal foil surface may be reduced if necessary, or roughening treatment may not be performed.

One or more layers selected from a heat-resisting treated layer, an anti-rust layer and a chromate-treated layer may be formed between the metal foil and the surface-treated layer in order to improve various properties. Those layers may be a single layer or multiple layers.

It is preferable that the above laminate has an adhesion strength between the metal foil and the fluororesin film of 0.8 N/mm or more. Using the method described above allows the laminate to have such adhesion strength. By setting the adhesion strength to 0.9 N/mm or more, or 1.0 N/mm or more, the laminate may be suitably used as a metal-clad laminate or a substrate for circuits. The adhesion strength as used herein means the adhesion strength measured under conditions described in Examples. In the case of a laminate prepared by bonding metal foil to the surface-treated side of a fluororesin film having only one side surface-treated, the non-treated side of the fluororesin film may also be surface-modified in order to improve adhesiveness of the laminate to other materials.

The metal-clad laminate of the present disclosure may further have a layer other than the metal foil or the fluororesin film. It is preferable that the layer other than the metal foil or the fluororesin film is at least one selected from the group consisting of polyimide, liquid crystal polymer, polyphenylene sulfide, a cycloolefin polymer, polystyrene, epoxy resin, bismaleimide, polyphenylene oxide, polyphenylene ether, and polybutadiene.

The layer other than the metal foil or the fluororesin film is not limited as long as it comprises the resin described above. It is also preferable that the layer other than the metal foil or the fluororesin film has a thickness in the range of 12.5 to 260 μm.

The laminated structure of the metal-clad laminate of the present disclosure can be suitably used for not only a long metal-clad laminate in which metal foil is stacked on one side or both sides of a roll film, but also a metal-clad laminate obtained by cutting out a roll film and stacking metal foil on the roll film.

In the metal-clad laminate of the present disclosure, the roll film of the present invention is unwound, and a metal layer is formed on the surface thereof. The metal layer can be formed on one side or both sides of the roll film. Examples of methods for forming a metal layer include a method of stacking (adhering) metal foil to the surface of a roll film, an evaporation method, and a plating method. Examples of methods for laminating metal foil include a method by heat pressing. Examples of temperature of heat pressing include a melting point of dielectric film −150° C. to a melting point of dielectric film +40° C. Examples of time of heat pressing include 1 to 30 minutes. The pressure of heat pressing can be produced by the method of 0.1 to 10 MPa.

The application of the metal-clad laminate of the present disclosure is not limited, and the metal-clad laminate of the present disclosure is used as a substrate for circuits. A printed circuit board is a plate-like part that electrically connects electronic components such as semiconductors and capacitor chips while arranging and fixing those in a limited space. The configuration of the printed circuit board formed from the metal-clad laminate of the present disclosure is not limited. The printed circuit board may be a rigid circuit board, a flexible circuit board, or a rigid-flexible circuit board. The printed circuit board may be any of a single-sided substrate, a double-sided substrate, or a multilayer substrate (such as a build-up substrate). The metal-clad laminate of the present disclosure can be particularly suitably used for flexible circuit boards and rigid circuit boards.

The substrate for circuits is not limited, and can be produced by general methods using the metal-clad laminate described above.

The laminate for a circuit board also includes a laminate comprising a metal foil layer, the above fluororesin film, and a substrate layer. The substrate layer is not limited. It is preferable that the laminate has a fabric layer made of glass fiber and a resin film layer.

The above fabric layer made of glass fiber is made of, for example, glass cloth or glass non-woven fabric.

Commercially available glass cloth may be used, and glass cloth which has been treated with a silane coupling agent is preferred in order to improve affinity with fluororesin. Materials of glass cloth include E-glass, C-glass, A-glass, S-glass, D-glass, NE-glass and low dielectric glass. E-glass, S-glass and NE-glass are preferred because they are readily available. The type of weaving fiber may be plain weave or twill weave. The glass cloth has a thickness of usually 5 to 90 μm and preferably 10 to 75 μm. It is preferable to use the glass cloth thinner than the fluororesin film used.

For the above laminate, glass non-woven fabric may be used as the fabric layer made of glass fiber. Glass non-woven fabric refers to a fabric prepared by bonding glass staple fiber with a small amount of a binder compound (resin or an inorganic substance), or fabric in which pieces of glass staple fiber are entangled to maintain the shape without using a binder compound. Commercially available ones may be used. The glass staple fiber has a diameter of preferably 0.5 to 30 μm, and a fiber length of preferably 5 to 30 mm. Examples of binder compounds include a resin such as epoxy resin, acrylic resin, cellulose, polyvinyl alcohol and fluororesin, and an inorganic compound such as a silica compound. The amount of the binder compound used is usually 3 to 15% by mass based on the glass staple fiber. Materials of glass staple fiber include E-glass, C-glass, A-glass, S-glass, D-glass, NE-glass and low dielectric glass. The glass non-woven fabric has a thickness of usually 50 μm to 1,000 μm, and preferably 100 to 900 μm. The thickness of the glass non-woven fabric in the present application refers to values measured according to JIS P8118: 1998 using Digital Gauge DG-925 (load 110 g, diameter 10 mm) made by Ono Sokki Co., Ltd. To improve affinity with fluororesin, the glass non-woven fabric may be treated with a silane coupling agent.

Since most glass non-woven fabrics have a very high porosity of 80% or more, it is preferable to use a glass non-woven fabric thicker than the sheet of fluororesin; and it is preferable to compress glass non-woven fabric under pressure and then used.

The above fabric layer made of the glass fiber may be a layer in which glass cloth and glass non-woven fabric are stacked. This combines both features and provides suitable qualities.

The fabric layer made of the glass fiber may be in the form of prepreg which has been impregnated with resin.

In the above laminate, the fabric layer made of glass fiber may be bonded to the fluororesin film at the interface, or the fabric layer made of glass fiber may be partly or entirely impregnated with the fluororesin film.

Furthermore, prepreg may be prepared by impregnating fabric made of glass fiber with a fluororesin composition. The prepreg prepared as described above may be stacked with the fluororesin film of the present disclosure. In that case, the fluororesin composition used for preparing prepreg is not limited, and the fluororesin film of the present disclosure may be used.

Heat resistant resin film and thermosetting resin film are preferred as the resin film used as the above substrate layer. Examples of heat resistant resin film include polyimide, liquid crystal polymer, and polyphenylene sulfide. Examples of thermosetting resins include those including epoxy resin, bismaleimide, polyphenylene oxide, polyphenylene ether and polybutadiene.

The heat resistant resin film and the thermosetting resin film may also include reinforcing fiber. Examples of reinforcing fibers include, but are not limited to, glass cloth, in particular preferably low dielectric glass cloth.

Properties of the heat resistant resin film and the thermosetting resin film, such as dielectric properties, linear expansion coefficient and water absorption ratio are not limited. For example, the dielectric constant at 20 GHz is preferably 3.8 or less, more preferably 3.4 or less and further preferably 3.0 or less. The dielectric loss tangent at 20 GHz is preferably 0.0030 or less, more preferably 0.0025 or less, and further preferably 0.0020 or less. The linear expansion coefficient is preferably 100 ppm/° C. or less, more preferably 70 ppm/° C. or less, and further preferably 40 ppm/° C. or less. The water absorption is preferably 1.0% or less, more preferably 0.5% or less, and further preferably 0.1% or less.

### EXAMPLES

The present disclosure will be described in more detail with reference to Examples. In the following Examples, the ratio is expressed as a molar ratio.

### Example 1

Pellets of copolymer composition TFE/PPVE=98.6/1.4, MFR 15.2 g/10 minutes, melting point 309.5° C. were fed into a 360° C. extruder, extruded from a 1,700 mm wide T die, picked up onto a metal cooling roll, and further taken up on a winding core to form a roll film of 1, 300 mm width and 50 μm thickness. At that time, the air gap was set to 60 mm. Both surfaces of the film were further subjected to a corona treatment to obtain a roll film having the number of unstable functional groups of 324 (per 10⁶ carbon atoms). The corona treatment was performed by surface-treating both surfaces of the roll film obtained by extrusion (both surfaces of the film were subjected to corona discharge treatment by passing the film continuously along a roll-shaped ground electrode with allowing nitrogen gas containing 0.50% by volume of vinyl acetate to flow near the discharge electrode and the roll-shaped ground electrode in a corona discharge device at an amount of discharge of 1,324 W·minute/m²).

### Example 2

Example 2 was performed in the same manner as in Example 1 except that pellets of copolymer composition TFE/PPVE=98.2/1.8, MFR 15.8 g/10 minutes, and melting point 305.3° C. were used. Both surfaces of the film were subjected to a corona treatment to obtain a roll film having the number of unstable functional groups of 307 (per 10⁶ carbon atoms).

The film was further subjected to an annealing treatment with a transport tension of 0.5 N at 180° C. for 2 minutes.

The roll film was unwound and cut into a length of 15 cm×width of 15 cm, and an electrolytic copper foil CF-T9DA-SV18 (thickness 18 μm/Rz 0.85 μm) (made by Fukuda Metal Foil & Powder Co., Ltd.) of the same size was bonded to one surface of the film, and then subjected to a vacuum heat press to obtain a copper-clad laminate.

### Example 3

Example 3 was performed in the same manner as in Example 2 except that a roll film with a thickness of 25 μm was formed.

### Example 4

Example 4 was performed in the same manner as in Example 3 except that a roll film with a thickness of 12.5 μm was formed.

### Example 5

Example 5 was performed in the same manner as in Example 1 except that pellets of copolymer composition TFE/PPVE=97.5/2.5, MFR 21.0 g/10 minutes, a melting point of 303° C., and glass transition temperature of 93° C. were used. Both surfaces of the film were subjected to a corona treatment to obtain a roll film having the number of unstable functional groups of 201 (per 10⁶ carbon atoms).

### Example 6

Example 6 was performed in the same manner as in Example 1 except that pellets of copolymer composition TFE/PPVE=97.7/2.3, MFR 14.6 g/10 minutes, and a melting point of 300.9° C. were used. Both surfaces of the film were subjected to a corona treatment to obtain a roll film having the number of unstable functional groups of 192 (per 10⁶ carbon atoms).

### Example 7

Example 7 was performed in the same manner as in Example 1 except that pellets of copolymer composition TFE/PPVE/HFP=98.5/1.1/0.4 and MFR 24.0 g/10 minutes were used. Both surfaces of the film were subjected to a corona treatment to obtain a roll film having the number of unstable functional groups of 126 (per 10⁶ carbon atoms).

### Example 8

Example 8 was performed in the same manner as in Example 7 except that a roll film with a thickness of 25 μm was formed.

### Example 9

Example 9 was performed in the same manner as in Example 7 except that a roll film with a thickness of 12.5 μm was formed.

### Example 10

Example 10 was performed in the same manner as in Example 1 except that pellets of copolymer composition TFE/PPVE=97.7/2.3, MFR 14.8 g/10 minutes, and a melting point of 300.9° C. were used. Both surfaces of the film were subjected to a corona treatment to obtain a roll film having the number of unstable functional groups of 38 (per 10⁶ carbon atoms).

### Example 11

Example 11 was performed in the same manner as in Example 1 except that pellets of copolymer composition TFE/PPVE=97.4/2.6, MFR 25.0 g/10 minutes, a melting point of 304° C., and glass transition temperature of 93° C. were used. Both surfaces of the film were subjected to a corona treatment to obtain a roll film having the number of unstable functional groups of 15 (per 10⁶ carbon atoms).

### Example 12

Example 12 was performed in the same manner as in Example 1 except that pellets of copolymer composition TFE/PPVE=97.7/2.3, MFR 15.0 g/10 minutes, and a melting point of 300.9° C. were used. Both surfaces of the film were subjected to a corona treatment to obtain a roll film having the number of unstable functional groups of 8 (per 10⁶ carbon atoms).

### Example 13

Example 13 was performed in the same manner as in Example 12 except that a roll film with a thickness of 25 μm was formed.

### Example 14

Example 14 was performed in the same manner as in Example 12 except that a roll film with a thickness of 12.5 μm was formed.

### Example 15

Example 15 was performed in the same manner as in Example 12 except that the pellets were extruded from a 1,000 mm wide T die, picked up onto a metal cooling roll, and further taken up on a winding core to form a roll film of 500 mm width.

### Example 16

Example 16 was performed in the same manner as in Example 15 except that a roll film with a thickness of 25 μm was formed.

### Example 17

Example 17 was performed in the same manner as in Example 15 except that a roll film with a thickness of 12.5 μm was formed.

### Example 18

Example 18 was performed in the same manner as in Example 15 except that the air gap was set to 50 mm.

### Comparative Example 1

Comparative Example 1 was performed in the same manner as in Example 15 except that the air gap was set to 70 mm.

### Comparative Example 2

Comparative Example 2 was performed in the same manner as in Example 15 except that the air gap was set to 80 mm.

### Comparative Example 3

Comparative Example 3 was performed in the same manner as in Example 2 except that the air gap was set to 70 mm. Both surfaces of the film were subjected to a corona treatment to obtain a roll film having the number of unstable functional groups of 307 (per 10⁶ carbon atoms).

### Comparative Example 4

Comparative Example 4 was performed in the same manner as in Example 1 except that pellets of copolymer composition TFE/PPVE=98.2/1.8 and MFR 14.0 g/10 minutes were used. Both surfaces of the film were subjected to a corona treatment to obtain a roll film having the number of unstable functional groups of 390 (per 10⁶ carbon atoms).

### Comparative Example 5

Comparative Example 5 was performed in the same manner as in Comparative Example 4 except that a roll film with a thickness of 25 μm was formed.

### Comparative Example 6

Comparative Example 6 was performed in the same manner as in Comparative Example 4 except that a roll film with a thickness of 12.5 μm was formed.

### Comparative Example 7

Comparative Example 7 was performed in the same manner as in Example 1 except that pellets of copolymer composition TFE/PPVE=97.2/2.8, MFR 64.0 g/10 minutes, a melting point of 284° C., and glass transition temperature of 90° C. were used. Both surfaces of the film were subjected to a corona treatment to obtain a roll film having the number of unstable functional groups of 507 (per 10⁶ carbon atoms).

### (Evaluation Method)

(Number of unstable functional groups per 1×10⁶ carbon atoms in main chain of fluororesin)

For the number of unstable functional groups, the film was analyzed using FT-IR Spectrometer 1760X (made by Perkin-Elmer).

### (Glass Transition Temperature)

Glass transition temperature was determined by performing dynamic viscoelasticity measurement using DVA-220 (made by ITK Co., Ltd.). The measurement was performed using a compression-formed sheet with a length of 25 mm, a width of 5 mm, and a thickness of 0.2 mm as a sample test piece at a heating rate of 5° C./minute and a frequency of 10 Hz, and the temperature at the peak of tan 8 value was taken as the glass transition temperature.

### (Film Width)

The film width was measured with a metal ruler.

### (Film Thickness)

Film thickness was measured every 5 mm in the same width direction as shown in the FIGURE. This measurement was performed using a tabletop offline contact-type thickness measuring device made by Yamabun Electronics Co., Ltd. Furthermore, the film thicknesses of 12 points were measured at every 20 cm in a travel direction at every 5 mm. The average of entire film thicknesses measured in this way was shown in the table as “average film thickness of surface” (a). Furthermore, each average thickness of 12 points in the travel direction measured at the same value in the width direction was calculated, and the difference between the maximum value (b) thereof and the average film thickness of surface (a) was calculated.

### (Air Gap)

The distance from the lip tip where the melted resin in the T-die flowed out to a point where the melted resin contacted with the first roll was measured with a metal ruler.

### (Gauge Band)

The formed roll film was stored in a warehouse where temperature and humidity were not controlled, and left for 1 month, and then the gauge band of the roll film was evaluated. The evaluation of the gauge band of the roll film was performed visually, and when a gauge band was observed, it was evaluated as “presence”, and when not observed, it was evaluated as “absence”.

### (Shape: Presence or Absence of Curls)

A fluororesin film which had not been preheated or which had been preheated at the glass transition temperature or more and less than the melting point was stacked in the order of copper foil/fluororesin film to prepare a 100 mm square laminate using a vacuum heat press, and the presence or absence of curls was visually inspected. The copper foil used was electrolytic copper foil CF-T9DA-SV-18 (thickness 18 μm/Rz 0.85 μm) (made by Fukuda Metal Foil & Powder Co., Ltd.).

(Shrinkage Rate after Copper Foil Etching)

The annealed film and electrolytic copper foil CF-T9DA-SV-18 (thickness 18 μm/Rz 0.85 μm) (made by Fukuda Metal Foil & Powder Co., Ltd.) were heat-pressed using a vacuum heat press (Model: MKP-1000HVWH-S7, made by Mikado Technos Co., Ltd.) at a press temperature of 320° C. for a preheating time of 60 seconds at a pressure of 1.5 MPa for a pressing time of 300 seconds to bond the surface-treated surface of the fluororesin film to the copper foil. Each fluorine film side of the two resulting single-sided copper-clad laminate was surface-treated. A piece of the single-sided copper-clad laminate, a piece of prepreg R-5680 (N) (thickness 80 μm) (made by Panasonic Corporation) and a piece of the single-sided copper-clad laminate were stacked in this order so that the treated surface was combined with prepreg, and they were bonded using a vacuum heat press at a press temperature of 200° C. to give a double-sided copper-clad laminate.

After measuring the dimensions of the resulting double-sided copper-clad laminate, the copper foil on both sides was removed, and further the laminate was heated at 150° C. for 30 minutes. Then, the dimensions were measured, and the rate of change was then calculated.

### (Characteristic Impedance)

The annealed film and electrolytic copper foil CF-T9DA-SV-18 (thickness 18 μm/Rz 0.85 μm) (made by Fukuda Metal Foil & Powder Co., Ltd.) were heat-pressed using a vacuum heat press (Model: MKP-1000HVWH-S7, made by Mikado Technos Co., Ltd.) at a press temperature of 320° C. for a preheating time of 60 seconds at a pressure of 1.5 MPa for a pressing time of 300 seconds to bond the surface-treated surface of the fluororesin film to the copper foil. Each fluorine film side of the two resulting single-sided copper-clad laminate was surface-treated. A piece of the single-sided copper-clad laminate, a piece of prepreg R-5680 (N) (thickness 80 μm) (polyphenylene ether (PPE) resin cured product, made by Panasonic Corporation) and a piece of the single-sided copper-clad laminate were stacked in this order so that the treated surface was combined with prepreg, and they were bonded using a vacuum heat press at a press temperature of 200° C. to give a double-sided copper-clad laminate. With this, a substrate was produced, and the characteristic impedance was measured based on the TDR method.

### (MFR)

The melt flow rate was measured in accordance with ASTM D3307 under conditions of a temperature of 372° C. and a load of 5.0 kg.

### (Rz)

Rz in the range of 200 μm² was measured using a color 3D laser microscope VK-9700 made by KEYENCE CORPORATION.

### (Adhesion Strength)

The film formed in Example 2 and electrolytic copper foil CF-T9DA-SV-18 (thickness 18 μm/Rz 0.85 μm) (made by Fukuda Metal Foil & Powder Co., Ltd.) were stacked in the order of the copper foil, the fluororesin film and the copper foil, and heat-pressed using a vacuum heat press (Model: MKP-1000HVWH-S7, made by Mikado Technos Co., Ltd.) at a press temperature of 320° C. for a preheating time of 60 seconds at a pressure of 1.5 MPa for a pressing time of 300 seconds to prepare a laminate. An aluminum plate was attached to one side of the laminate with adhesive tape, and peel strength was measured by sandwiching and pulling copper foil at a width of 10 mm in the direction at 90° relative to the plane of the laminate at a rate of 50 mm per minute using Tensilon Universal Testing Machine (made by Shimadzu Corporation). The resulting value was defined as adhesion strength. The result was 1.3 N/mm.

### (Measurement Method of Characteristic Impedance)

The annealed film and electrolytic copper foil CF-T9DA-SV-18 (thickness 18 μm/Rz 0.85 μm) (made by Fukuda Metal Foil & Powder Co., Ltd.) were heat-pressed using a vacuum heat press (Model: MKP-1000HVWH-S7, made by Mikado Technos Co., Ltd.) at a press temperature of 320° C. for a preheating time of 60 seconds at a pressure of 1.5 MPa for a pressing time of 300 seconds to bond the surface-treated surface of the fluororesin film to the copper foil. Each fluorine film side of the two resulting single-sided copper-clad laminate was surface-treated. A piece of the single-sided copper-clad laminate, a piece of prepreg R-5680 (N) (thickness 80 μm) (polyphenylene ether (PPE) resin cured product, made by Panasonic Corporation) and a piece of the single-sided copper-clad laminate were stacked in this order so that the treated surface was combined with prepreg, and they were bonded using a vacuum heat press at a press temperature of 200° C. to give a double-sided copper-clad laminate. Subsequently, a substrate in which a microstrip line was provided on one side of the copper foil was formed. The line width of the line was designed so that the characteristic impedance was 50Ω using the thickness of the film, the specific dielectric constant of the material, and the thickness of the copper foil. The characteristic impedance was measured based on the TDR method using a vector network analyzer by putting probers on both ends of the created substrate for evaluation.

TABLE 2

| | | Example | Example | Example | Example | Example | Example | Example | Example | Example |
|---|---|---|---|---|---|---|---|---|---|---|
| | | 1 | 2 | 3 | 4 | 5 | 6 | 7 | 8 | 9 |
| Film | Number of unstable | 324 | 307 | 307 | 307 | 201 | 192 | 126 | 126 | 126 |
| | functional groups per | | | | | | | | | |
| | 1 × 10⁶ carbon atoms | | | | | | | | | |
| | Film width (mm) | 1300 | ← | ← | ← | ← | ← | ← | ← | ← |
| | Average film thickness | 50 | 50 | 25 | 12.5 | 50 | 50 | 50 | 25 | 12.5 |
| | of surface (um) | | | | | | | | | |
| | Maximum value of | 51.6 | 51.6 | 26.5 | 13.7 | 51.6 | 51.5 | 51.5 | 26.3 | 13.6 |
| | average film thicknesses | | | | | | | | | |
| | at each position in | | | | | | | | | |
| | width direction | | | | | | | | | |
| | (average film thicknesses | | | | | | | | | |
| | in travel direction | | | | | | | | | |
| | at every 5 mm in | | | | | | | | | |
| | width direction) | | | | | | | | | |
| | Average in travel | 1.6 | 1.6 | 1.5 | 1.2 | 1.6 | 1.5 | 1.5 | 1.3 | 1.1 |
| | direction at each | | | | | | | | | |
| | position (um) | | | | | | | | | |
| | Air gap (mm) | 60 | ← | ← | ← | ← | ← | ← | ← | ← |
| | Gauge band | absence | absence | absence | absence | absence | absence | absence | absence | absence |
| Laminate of | Shape (presence or | absence | absence | absence | absence | absence | absence | absence | absence | absence |
| copper foil | absence of curls) | | | | | | | | | |
| and film (RCC) | | | | | | | | | | |
| Laminate | Shrinkage rate after | — | 0.09 | 0.08 | 0.07 | — | — | 0.09 | 0.08 | 0.07 |
| of RCC and | copper foil etching | | | | | | | | | |
| thermosetting | (Evaluation at 150° C. | | | | | | | | | |
| resin | for 30 minutes) | | | | | | | | | |
| | Acceptance criteria | | | | | | | | | |
| | within 0.1% Copper | | | | | | | | | |
| | foil/PFA/PPE/PFA/ | | | | | | | | | |
| | copper foil | | | | | | | | | |
| Substrate | Surface treatment/ | — | performed | performed | performed | — | — | performed | performed | performed |
| data | Evaluation with | | | | | | | | | |
| | microstrip line | | | | | | | | | |
| | Characteristic | — | 51.0 | 51.8 | 52.9 | — | — | 50.9 | 51.6 | 52.6 |
| | impedance (Ω) | | | | | | | | | |
| | Acceptance range | — | OK | OK | OK | — | — | OK | OK | OK |
| | within 53.0 Ω | | | | | | | | | |

| | | | | | | | | | |
|---|---|---|---|---|---|---|---|---|---|
| MFR | 15.2 | 15.8 | 15.8 | 15.8 | 21.0 | 14.6 | 24.0 | 24.0 | 24.0 |

TABLE 3

| | | Example | Example | Example | Example | Example | Example | Example | Example | Example |
|---|---|---|---|---|---|---|---|---|---|---|
| | | 10 | 11 | 12 | 13 | 14 | 15 | 16 | 17 | 18 |
| Film | Number of unstable | 38 | 15 | 8 | 8 | 8 | 8 | 8 | 8 | 8 |
| | functional groups per | | | | | | | | | |
| | 1 × 10⁶ carbon atoms | | | | | | | | | |
| | Film width (mm) | ← | ← | ← | ← | ← | 500 | ← | ← | 500 |
| | Average film thickness | 50 | 50 | 50 | 25 | 12.5 | 50 | 25 | 12.5 | 50 |
| | of surface (um) | | | | | | | | | |
| | Maximum value of | 51.4 | 51.3 | 51.3 | 26.3 | 13.5 | 50.7 | 25.6 | 13.0 | 50.6 |
| | average film thicknesses | | | | | | | | | |
| | at each position in | | | | | | | | | |
| | width direction | | | | | | | | | |
| | (average film thicknesses | | | | | | | | | |
| | in travel direction at | | | | | | | | | |
| | every 5 mm in | | | | | | | | | |
| | width direction) | | | | | | | | | |
| | Average in travel | 1.4 | 1.3 | 1.3 | 1.3 | 1.0 | 0.7 | 0.6 | 0.5 | 0.6 |
| | direction at each | | | | | | | | | |
| | position (um) | | | | | | | | | |
| | Air gap (mm) | ← | ← | ← | ← | ← | ← | ← | ← | 50 |
| | Gauge band | absence | absence | absence | absence | absence | absence | absence | absence | absence |
| Laminate of | Shape (presence or | absence | absence | absence | absence | absence | absence | absence | absence | absence |
| copper foil | absence of curls) | | | | | | | | | |
| and film (RCC) | | | | | | | | | | |
| Laminate | Shrinkage rate after | — | — | 0.09 | 0.08 | 0.07 | — | — | — | — |
| of RCC and | copper foil etching | | | | | | | | | |
| thermosetting | (Evaluation at 150° C. | | | | | | | | | |
| resin | for 30 minutes) | | | | | | | | | |
| | Acceptance criteria | | | | | | | | | |
| | within 0.1% Copper | | | | | | | | | |
| | foil/PFA/PPE/PFA/PPE | | | | | | | | | |
| Substrate | Surface treatment/ | — | — | performed | performed | performed | — | — | — | — |
| data | Evaluation with | | | | | | | | | |
| | microstrip line | | | | | | | | | |
| | Characteristic | — | — | 50.8 | 51.6 | 52.4 | — | — | — | — |
| | impedance (Ω) | | | | | | | | | |
| | Acceptance range | — | — | OK | OK | OK | — | — | — | — |
| | within 53.0 Ω | | | | | | | | | |

| | | | | | | | | | |
|---|---|---|---|---|---|---|---|---|---|
| MFR | 14.8 | 25.0 | 15.0 | 15.0 | 15.0 | 15.0 | 15.0 | 15.0 | 15.0 |

TABLE 4

| | | Comparative | Comparative | Comparative | Comparative | Comparative | Comparative | Comparative |
|---|---|---|---|---|---|---|---|---|
| | | Example 1 | Example 2 | Example 3 | Example 4 | Example 5 | Example 6 | Example 7 |
| Film | Number of | 8 | 8 | 307 | 390 | 390 | 390 | 507 |
| | unstable | | | | | | | |
| | functional | | | | | | | |
| | groups per | | | | | | | |
| | 1 × 10⁶ carbon | | | | | | | |
| | atoms | | | | | | | |
| | Film width (mm) | 500 | 500 | 1300 | ← | ← | ← | 1300 |
| | Average film | 50 | 50 | 50 | 50 | 25 | 12.5 | 50 |
| | thickness of | | | | | | | |
| | surface (um) | | | | | | | |
| | Maximum | 52.1 | 52.3 | 53.0 | 56.2 | 28.1 | 15.5 | 57.8 |
| | value of | | | | | | | |
| | average film | | | | | | | |
| | thicknesses at | | | | | | | |
| | each position | | | | | | | |
| | in width | | | | | | | |
| | direction | | | | | | | |
| | (average film | | | | | | | |
| | thicknesses in | | | | | | | |
| | travel | | | | | | | |
| | direction at | | | | | | | |
| | every 5 mm in | | | | | | | |
| | width | | | | | | | |
| | direction) | | | | | | | |
| | Average in | 2.1 | 2.3 | 3.0 | 6.2 | 3.1 | 3.0 | 7.8 |
| | travel | | | | | | | |
| | direction at | | | | | | | |
| | each position | | | | | | | |
| | (um) | | | | | | | |
| | Air gap (mm) | 70 | 80 | 70 | 60 | ← | ← | 60 |
| | Gauge band | presence | presence | presence | presence | presence | presence | presence |
| Laminate | Shape | presence | presence | presence | presence | presence | presence | presence |
| of copper | (presence or | | | | | | | |
| foil and | absence of | | | | | | | |
| film (RCC) | curls) | | | | | | | |
| Laminate | Shrinkage | — | — | 0.25 | 0.34 | 0.27 | 0.20 | — |
| of RCC and | rate after | | | | | | | |
| thermosetting | copper foil | | | | | | | |
| resin | etching | | | | | | | |
| | (Evaluation at | | | | | | | |
| | 150° C. for 30 | | | | | | | |
| | minutes) | | | | | | | |
| | Acceptance | | | | | | | |
| | criteria within | | | | | | | |
| | 0.1% Copper | | | | | | | |
| | foil/PFA/PPE/ | | | | | | | |
| | PFA/PPE | | | | | | | |
| Substrate | Surface | — | — | performed | performed | performed | performed | — |
| data | treatment/ | | | | | | | |
| | Evaluation | | | | | | | |
| | with microstrip | | | | | | | |
| | line | | | | | | | |
| | Characteristic | — | — | 57.0 | 53.7 | 53.7 | 57.2 | — |
| | impedance (Ω) | — | — | NG | NG | NG | NG | — |
| | Acceptance | | | | | | | |
| | range within | | | | | | | |
| | 53.0 Ω | | | | | | | |

| | | | | | | | |
|---|---|---|---|---|---|---|---|
| MFR | 15.0 | 15.0 | 15.8 | 14.0 | 14.0 | 14.0 | 64.0 |

### INDUSTRIAL APPLICABILITY

The fluororesin long film of the present disclosure can be used for a metal-clad laminate for substrate for circuits, or the like.

1. A fluororesin long film comprising a fluororesin in which the number of unstable functional groups is less than 350 per 1×10⁶ carbon atoms, wherein a difference between a maximum value of average film thicknesses in a travel direction each measured at every 5 mm in a width direction and an average film thickness of entire surface is within 2 μm.

2. The fluororesin long film according to claim 1, wherein the fluororesin long film comprises a tetrafluoroethylene-perfluoroalkyl vinyl ether copolymer (PFA) or a tetrafluoroethylene-hexafluoropropylene copolymer (FEP).

3. The fluororesin long film according to claim 1, wherein the number of unstable functional groups of the fluororesin is less than 20 per 1×10⁶ carbon atoms.

4. The fluororesin long film according to claim 1, wherein the fluororesin long film has an adhesion strength of 0.8 N/mm or more when bonded to metal foil having a surface roughness Rz of 1.5 μm or less.

5. The fluororesin long film according to claim 1, wherein the fluororesin long film is used for a metal-clad laminate.

6. A metal-clad laminate, comprising metal foil and the fluororesin film according to claim 1.

7. The metal-clad laminate according to claim 6, further comprising a layer other than the metal foil or the fluororesin film,
wherein the layer other than the metal foil or the fluororesin film is at least one selected from the group consisting of polyimide, liquid crystal polymer, polyphenylene sulfide, a cycloolefin polymer, polystyrene, epoxy resin, bismaleimide, polyphenylene oxide, polyphenylene ether and polybutadiene.

8. The metal-clad laminate according to claim 6, wherein the metal foil has a surface roughness Rz of 1.5 μm or less.

9. The metal-clad laminate according to claim 6, wherein the metal-clad laminate has an adhesion strength between the metal foil and the fluororesin film of 0.8 N/mm or more.

10. A substrate for circuit, comprising the metal-clad laminate according to claim 6.
